(19) United States
(12) Patent Application Publication
(10) Pub. No.: US 2026/0255825 A1
(43) Pub. Date: Aug. 27, 2026

(54) DISPLAY DEVICE

(71) Applicant: LG Display Co., Ltd., Seoul (KR)

(72) Inventors: Changhyun JUNG, Paju-si (KR); Kyoungmook LEE, Paju-si (KR); Kwonyeong EUN, Paju-si (KR)

(21) Appl. No.: 19/551,706

(22) Filed: Feb. 27, 2026

(30) Foreign Application Priority Data
Feb. 27, 2025 (KR) 10-2025-0025870

(51) Int. Cl. H10K 59/131; H10H 29/49; H10K 59/35

(52) U.S. Cl. CPC H10K 59/131; H10H 29/49; H10K 59/35

(57) ABSTRACT

A display device includes a substrate including a display area including pixels and a non-display area around the display area, a low potential line on the substrate and extending along a first direction, a first electrode on the low potential line and disposed in each sub-pixel of each pixel, auxiliary pad electrodes, and a second electrode disposed on an auxiliary pad electrode among the auxiliary pad electrodes and on the first electrode The display area includes a first display area and a second display area between the first display area and the non-display area, the second electrode is electrically connected to the auxiliary pad electrode through a first contact hole, and a number of auxiliary pad electrodes per area in a central portion of the display area is greater than a number of auxiliary pad electrodes per area in an outer portion of the display area.

### CROSS REFERENCE TO RELATED APPLICATION

Pursuant to 35 U.S.C. § 119(a), this application claims the benefit of an earlier filing date and right of priority to Korean Patent Application No. 10-2025-0025870, filed on February 27, 2025, the entire contents of which is incorporated herein for all purposes by this reference.

### TECHNICAL FIELD

The present specification relates to a display device.

### BACKGROUND

As information society develops, demand for display devices for displaying images are increasing, and various types of display devices such as liquid crystal display (LCD) devices and organic light emitting diode (OLED) display devices are utilized.

### SUMMARY

According to one implementation, there is provided a display device including a substrate including a display area including pixels and a non-display area around the display area, a low potential line disposed on the substrate and extending along a first direction, a first electrode disposed on the low potential line and disposed in each sub-pixel of each pixel, a plurality of auxiliary pad electrodes, and a second electrode on an auxiliary pad electrode among the plurality of auxiliary pad electrodes and on the first electrode, in which the display area includes a first display area and a second display area between the first display area and the non-display area, the second electrode is electrically connected to the auxiliary pad electrode through a first contact hole, and number of auxiliary pad electrodes per area in a central portion of the display area is greater than a number of auxiliary pad electrodes per area in an outer portion of the display area.

Detailed matters of other implementations are included in the detailed description and accompanying drawings.

### BRIEF DESCRIPTION OF THE DRAWINGS

FIG. 1 is a plan view of an example of a display device according to one implementation.

FIG. 2 is an example of a cross-sectional view along line A-A’ in FIG. 1.

FIG. 3 is a circuit diagram of an example of a pixel according to one implementation.

FIG. 4 is an example of a plan view of a display area of FIG. 1.

FIG. 5 is an example of a plan view of a first display area in FIG. 4.

FIG. 6 is an example of a cross-sectional view along line B-B’ in FIG. 5.

FIG. 7 is an example of a cross-sectional view along line C-C’ in FIG. 5.

FIG. 8 is an example of a plan view of a second display area in FIG. 4.

FIG. 9 is an example of a plan view of a first display area of a display panel according to another implementation.

FIG. 10 is an example of a cross-sectional view along line D-D’ in FIG. 9.

### DETAILED DESCRIPTION

A display device includes a plurality of pixels and a plurality of switching elements for driving and controlling the pixels.

Implementations of the present disclosure can provide a display device capable of minimizing a voltage drop of a low potential voltage in a central portion of a display panel.

Hereinafter, implementations will be described with reference to the accompanying drawings.

The same reference numerals indicate the same components. In addition, in the drawings, thicknesses, proportions, and dimensions of components can be exaggerated for effective description of technical contents. Scales of components illustrated in the drawings differ from the actual scale for convenience of description, and thus are not limited to the scales illustrated in the drawings.

In the specification, when a certain component (or an area, a layer, a portion, etc.) is described as “on,” “connected,” or “coupled to” another component, it means that the certain component may be directly connected/coupled to another component or still another component may be disposed therebetween.

The term “and/or” includes all one or more combinations that may be defined by the associated configurations.

Terms such as “under,” “at a lower side,” “above,” and “at an upper side” are used to describe the relationship between the components illustrated in the drawings. The terms are relative concepts and are described with respect to directions marked in the drawings. For example, as long as “immediately” or “directly” is not used, one or more other portions may be positioned between two portions. The spatially relative terms “below or beneath,” “lower,” “above,” “upper,” etc. can be used to easily describe the correlation with one element or components and another element or components as shown in the drawings. The spatially relative terms should be understood as the terms including different directions of elements in use or operation in addition to the directions shown in the drawings. For example, in case of turning the element shown in the drawing upside down, an element described as being disposed “below” or “beneath” another element may be disposed “above” another element. Accordingly, the example term “below” may include both downward and upward directions.

It should be understood that term such as “includes” or “has” is intended to specify the presence of features, numbers, steps, operations, components, parts, or a combination thereof described in the specification and does not preclude the presence or addition possibility of one or more other features, numbers, steps, operations, components, parts, or combinations thereof in advance.

Features of various implementations of the present specification may be coupled or combined partially or entirely, various technological interworking and driving are made possible, and the implementations may be implemented independently of each other or implemented together in an associated relationship.

Hereinafter, a display device of the present specification will be described with reference to the accompanying drawings and implementations as follows.

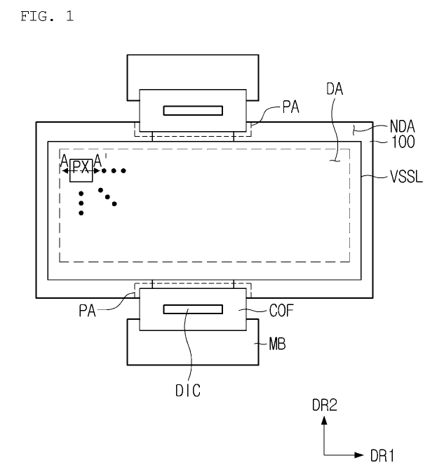

FIG. 1 is an example of a plan view of a display device according to one implementation.

Referring to FIG. 1, a display device 1 according to one implementation may include a display panel 100, a chip on film COF, and a main substrate MB. The display panel 100 may include a display area DA and a non-display area NDA positioned near the display area DA. The display area DA may include a plurality of pixels PX. The flat surface shape of the display area DA may have a rectangular shape. However, the implementations of the present specification are not limited thereto, and the flat surface shape of the display area DA may be a square, circular, elliptical, or other polygonal shapes. For example, the display area DA may have a rectangular shape with rounded corners, but is not limited thereto and may also have a rectangular shape with angled corners.

In implementations, a first direction DR1 and a second direction DR2 are different directions and intersect each other, for example, directions that intersect vertically in a plan view. In FIG. 1, the first direction DR1 may be generally the same as an extension direction of short sides of the display panel 100, and the second direction DR2 may be the same as an extension direction of long sides of the display panel 100. However, the directions described in the implementations should be understood as indicating relative directions, and the implementations are not limited to the described directions.

The display area DA may include short sides extending in the first direction DR1 and long sides extending in the second direction DR2. In some implementations, the non-display area NDA may surround the display area DA. For example, the non-display area NDA may be disposed at one side and the other side of the display area DA in the first direction DR1 and one side and the other side of the display area DA in the second direction DR2.

The non-display area NDA may include a pad area PA. The pad area PA may be disposed in the non-display area NDA at the other side in the second direction DR2 and the non-display area NDA at one side in the second direction DR2, but the implementations of the present specification are not limited thereto.

The chip on film COF may be disposed in the pad area PA. The chip on film COF may include a data driving chip DIC. A low potential line VSSL may extend from the chip on film COF. Each of the low potential lines VSSL extending from the chip on film COF may extend to surround the display area DA. The arrangement of the low potential line VSSL in the non-display area NDA illustrated in FIG. 1 may be different depending on the design. In the non-display area NDA, the low potential line VSSL is not illustrated, but may be electrically connected to a second electrode (or an electrode that serves as a cathode electrode). The second electrode may be integrally disposed in the display area DA and the non-display area NDA.

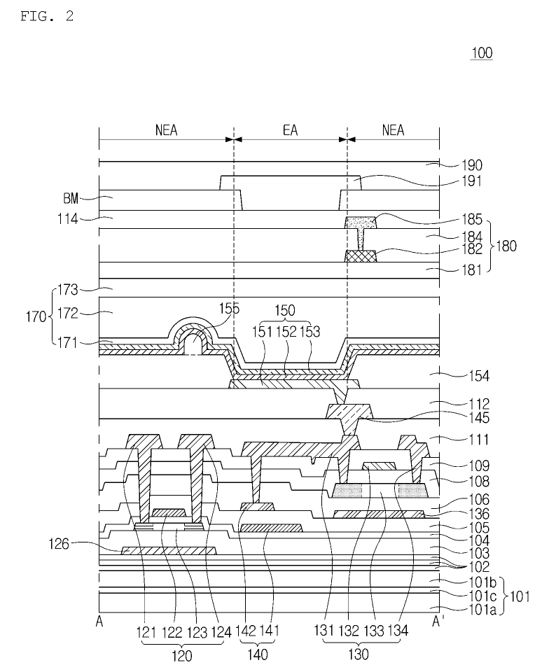

FIG. 2 is an example of a cross-sectional view along line A-A’ in FIG. 1.

Referring to FIG. 2, the display panel 100 may include a substrate 101, a buffer layer 102, a first thin film transistor 120, a second thin film transistor 130, a storage electrode 140, a light-emitting part 150, an encapsulation part 170, a touch part 180, and an upper organic layer 190.

The substrate 101 may include one or more plastic materials. For example, the substrate 101 may be a multi-substrate including a plurality of plastic materials such as polyimide, but is not limited thereto. For example, the substrate 101 may include a first substrate portion 101a and a second substrate portion 101b that include an organic material, and a third substrate portion 101c including an inorganic material, but the implementations of the present specification are not limited thereto.

A buffer layer 102 may be disposed on the substrate 101. The buffer layer 102 can minimize or delay the diffusion of moisture or oxygen penetrating the substrate 101. The buffer layer 102 may be formed by alternately laminating silicon nitride (SiNₓ) and silicon oxide (SiOₓ) at least once, but is not limited thereto.

A first light-shielding layer 126 may be disposed on the buffer layer 102. The first light-shielding layer 126 can prevent light from transmitting a first semiconductor layer 123 of the first thin film transistor 120. For example, the first semiconductor layer 123 may be disposed to overlap the first light-shielding layer 126.

A first insulating layer 103 may be disposed on the first light-shielding layer 126. The first insulating layer 103 may be made of the same material as the buffer layer 102, but is not limited thereto.

The first thin film transistor 120 may be disposed on the first insulating layer 103. The first thin film transistor 120 may include a first source electrode 121, a first gate electrode 122, the first semiconductor layer 123, and a first drain electrode 124.

The first semiconductor layer 123 may be disposed on the first insulating layer 103. The first semiconductor layer 123 may include a metal oxide semiconductor, such as indium-gallium-zinc oxide (IGZO), and a silicon-based semiconductor material, such as amorphous silicon or polycrystalline silicon, but is not limited thereto. The first semiconductor layer 123 may include a channel area, a source area, and a drain area.

The second insulating layer 104 may be disposed on the first semiconductor layer 123. The second insulating layer 104 may be formed of the same material as the first insulating layer 103, but is not limited thereto.

The first gate electrode 122 may be disposed on the second insulating layer 104. The first gate electrode 122 may be disposed on the second insulating layer 104 to overlap the channel area of the first semiconductor layer 123. The first gate electrode 122 may be formed of a single layer or multiple layers made of molybdenum (Mo), copper (Cu), titanium (Ti), aluminum (Al), chromium (Cr), gold (Au), nickel (Ni), neodymium (Nd), or compounds thereof. The first gate electrode 122 may be disposed along with a gate line.

A third insulating layer 105 may be disposed on the first gate electrode 122. The third insulating layer 105 may be made of the same material as the first insulating layer 103 or the second insulating layer 104.

The first source electrode 121 and the first drain electrode 124 may be disposed on the third insulating layer 105.

The first source electrode 121 and the first drain electrode 124 may be electrically connected to the first semiconductor layer 123 through contact holes. The first source electrode 121 and the first drain electrode 124 may be formed of a metallic material.

The first source electrode 121 and the first drain electrode 124 may be disposed along with a data line.

A storage electrode 140 may be disposed to be spaced apart from the first thin film transistor 120. The storage electrode 140 may include a first storage electrode 141 and a second storage electrode 142.

The first storage electrode 141 may be disposed coplanarly with the first gate electrode 122 and may be made of the same material as the first gate electrode 122, but is not limited thereto.

The second storage electrode 142 may be disposed on the first storage electrode 141. The second storage electrode 142 may be disposed on the third insulating layer 105, and the third insulating layer 105 between the first storage electrode 141 and the second storage electrode 142 may be used as a dielectric to generate a capacitance.

The second thin film transistor 130 may be disposed to be spaced apart from the first thin film transistor 120 and the storage electrode 140. The second thin film transistor 130 may include a second source electrode 131, a second gate electrode 132, a second semiconductor layer 133, and a second drain electrode 134.

A second light-shielding layer 136 may be disposed on the same layer as the second storage electrode 142.

For example, the second semiconductor layer 133 may be disposed to overlap the second light-shielding layer 136.

A fourth insulating layer 106 may be disposed on the second light-shielding layer 136. The fourth insulating layer 106 may be made of the same material as the first insulating layer 103, the second insulating layer 104, or the third insulating layer 105, but is not limited thereto.

The second semiconductor layer 133 may be disposed on the fourth insulating layer 106. The second semiconductor layer 133 may include a source area, a drain area, and a channel area between the source area and the drain area.

The second semiconductor layer 133 may include a metal oxide semiconductor, such as indium-gallium-zinc oxide (IGZO), and a silicon-based semiconductor material, such as amorphous silicon or polycrystalline silicon, but is not limited thereto.

A fifth insulating layer 108 may be disposed on the second semiconductor layer 133. The fifth insulating layer 108 may be made of the same material as the first insulating layer 103, the second insulating layer 104, the third insulating layer 105, or the fourth insulating layer 106, but is not limited thereto.

The second gate electrode 132 may be disposed on the fifth insulating layer 108.

The second gate electrode 132 may be formed of the same material as the first gate electrode 122.

A sixth insulating layer 109 may be disposed on the second gate electrode 132. The sixth insulating layer 109 may be made of the same material as the first insulating layer 103, the second insulating layer 104, the third insulating layer 105, the fourth insulating layer 106, or the fifth insulating layer 108, but is not limited thereto.

The first source electrode 121, the first drain electrode 124, the third storage electrode 143, the second source electrode 131, and the second drain electrode 134 may be disposed on the sixth insulating layer 109.

The second source electrode 131 and the second drain electrode 134 may be formed of the same material as the first source electrode 121 and the first drain electrode 124 and disposed on the same layer.

The first thin film transistor 120 may be a switching transistor, and the second thin film transistor 130 may be a driving transistor, but the implementations of the present specification are not limited thereto.

A first protective layer 111 may be disposed on the first source electrode 121 and the first drain electrode 124.

The first protective layer 111 may planarize an upper portion of the first thin film transistor 120 and protect the first thin film transistor 120. The first protective layer 111 may be formed of an organic material.

A second protective layer 112 may be disposed on the first protective layer 111. The second protective layer 112 may be formed of the same material as the first protective layer 111, but is not limited thereto.

A connection electrode 145 may be disposed between the first protective layer 111 and the second protective layer 112.

The connection electrode 145 may electrically connect the second thin film transistor 130 to the light-emitting part 150.

The light-emitting part 150 may be disposed on the second protective layer 112. The light-emitting part 150 may include an anode electrode 151, an organic layer 152, and a cathode electrode 153.

The anode electrode 151 may be disposed on the second protective layer 112. The anode electrode 151 may be electrically connected to the first thin film transistor 120 through a contact hole formed in the second protective layer 112. The anode 151 may be a reflective electrode that reflects light, but is not limited thereto. The anode 151 may include a metal material with high reflectivity, such as a laminated structure (Ti/Al/Ti) of aluminum (Al) and titanium (Ti), a laminated structure (ITO/Al/ITO) of aluminum (Al) and indium tin oxide (ITO), or an APC alloy, and may be formed of a single layer or multiple layers, but is not limited thereto.

The organic layer 152 may be disposed on the anode electrode 151. The organic layer 152 may include one or more light-emitting structures (or light-emitting parts or elements) stacked on the anode electrode 151 in the order or reverse order of a hole transfer layer and an electron transfer layer. The organic layer 152 may be an organic light emitting layer, an inorganic light emitting layer, a quantum dot light emitting layer, a micro light emitting diode, a micro mini light emitting diode, or the like, but is not limited thereto.

The cathode electrode 153 may be disposed on the organic layer 152. The cathode 153 may be a transparent electrode that transmits light, but is not limited thereto. For example, the cathode electrode 153 may include a transparent conductive material, such as indium tin oxide (ITO) or indium zinc oxide (IZO), or a metal that transmits visible light.

A bank 154 may be disposed to expose the anode electrode 151. The bank 154 may define an opening (or a light-emitting area) of the sub-pixel and may be disposed to cover an edge portion of the anode electrode 151. Each sub-pixel may include a red light-emitting area, a green light-emitting area, and a blue light-emitting area. For example, the sub-pixel may be defined as a pixel, but is not limited by the term.

A spacer 155 may be further disposed on the bank 154.

The encapsulation part 170 may be disposed on the bank 154 or the light-emitting part 150. The encapsulation part 170 may include one or more insulating layers. For example, the encapsulation part 170 may include a first encapsulation layer 171, a second encapsulation layer 172 disposed on the first encapsulation layer 171, and a third encapsulation layer 173 disposed on the second encapsulation layer 172. The encapsulation part 170 may include one or more inorganic layers and one or more organic layers. For example, the first encapsulation layer 171 and the third encapsulation layer 173 may include an inorganic material, and the second encapsulation layer 172 may include an organic material.

A touch buffer layer 181 may be disposed on the encapsulation part 170. For example, the touch buffer layer 181 may be disposed on the third encapsulation layer 173. The touch buffer layer 181 may be made of the same material as the buffer layer 102. A first touch conductive layer may be disposed on the touch buffer layer 181. A touch insulating layer 184 may be disposed on the first touch conductive layer. The touch insulating layer 184 can prevent a short circuit between the touch electrodes. The touch insulating layer 184 may include an organic material or an inorganic material. FIG. 2 illustrates the touch insulating layer 184 including an organic material, but the implementations of the present specification are not limited thereto. A second touch conductive layer may be disposed on the touch insulating layer 184.

The first touch conductive layer may include a second touch electrode 182, and the second touch conductive layer may include a first touch electrode 185.

The second touch electrode 182 may be electrically connected to the first touch electrode 185 through a contact hole formed in the touch insulating layer 184.

The first touch electrode 185 and the second touch electrode 182 may include a metal material.

A color filter insulating layer 114 may be disposed on the touch part 180. The color filter insulating layer 114 may include an inorganic material, but the implementations of the present disclosure are not limited thereto.

A black matrix BM may be disposed on the color filter insulating layer 114. The black matrix BM may be disposed in the non-light-emitting area NEA.

A color filter 191 may be disposed on the black matrix BM and the color filter insulating layer 114. The color filter 191 may include a red color filter, a green color filter, or a blue color filter.

The upper organic layer 190 may be disposed on the color filter 191, but the implementations of the present specification are not limited thereto.

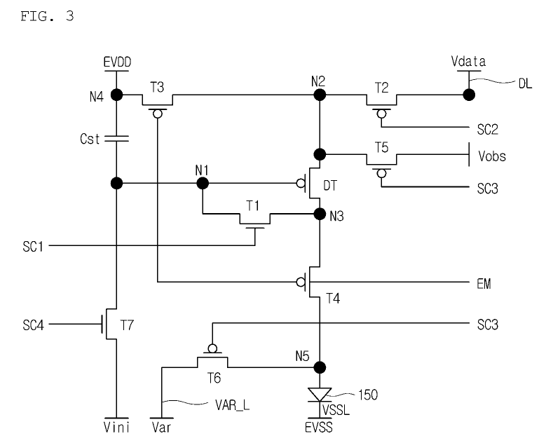

FIG. 3 is a circuit diagram of a pixel according to one implementation.

FIG. 3 illustrates an example of the pixel circuit for description, and the implementations of the present specification are not limited thereto as long as the pixel circuit has a structure that may control the light-emission of the light-emitting part 150 according to an applied light-emitting signal EM. For example, the pixel circuit may include an additional scan signal, a switching thin film transistor connected to the additional scan signal, and a switching thin film transistor to which an additional initialization voltage is applied, and a connection relationship between the switching elements or a connection location of a capacitor may be disposed in various ways. Hereinafter, for convenience of description, a display device having the pixel circuit structure of FIG. 3 will be described.

Referring to FIG. 3, each of the plurality of pixels include a pixel circuit having a driving transistor DT, and the light-emitting part 150 connected to the pixel circuit.

The pixel circuit may drive the light-emitting part 150 by controlling a driving current flowing in the light-emitting part 150. The pixel circuit may include the driving transistor DT, first to seventh transistors T1 to T7, and a capacitor Cst. Each of the transistors DT and T1 to T7 may include a first electrode, a second electrode, and a gate electrode. One of the first electrode and the second electrode may be a source electrode, and the other may be a drain electrode.

Each of the transistors DT and T1 to T7 may be a p-type thin film transistor or an n-type thin film transistor. In the implementation of FIG. 3, the first transistor T1 and the seventh transistor T7 are the n-type thin film transistors, and the remaining transistors DT and T2 to T6 are the p-type thin film transistors. However, the implementations of the present specification are not limited thereto, and all or some of the transistors DT and T1 to T7 may be the p-type thin film transistors or the n-type thin film transistors according to the implementations. In addition, the n-type thin film transistor may be an oxide thin film transistor including an oxide semiconductor layer, and the p-type thin film transistor may be a polycrystalline silicon thin film transistor including a polycrystalline semiconductor layer.

Hereinafter, an example in which the first transistor T1 and the seventh transistor T7 are the n-type oxide thin film transistors, and the remaining transistors DT and T2 to T6 are the p-type thin film transistors will be described. Accordingly, the first transistor T1 and the seventh transistor T7 are turned on by receiving a high voltage, and the remaining transistors DT and T2 to T6 are turned on by receiving a low voltage.

The first transistor T1 forming the pixel circuit may serve as a compensation transistor, a second transistor T2 may serve as a data supply transistor, third and fourth transistors T3 and T4 may serve as light-emitting control transistors, a fifth transistor T5 may serve as a bias transistor, and sixth and seventh transistors T6 and T7 may serve as initialization transistors.

The light-emitting part 150 may include an anode electrode (or a first electrode), and a cathode electrode (or a second electrode). The anode electrode of the light-emitting part 150 may be connected to a fifth node N5, and the cathode electrode thereof may be connected to a low potential driving voltage EVSS. The low potential driving voltage EVSS may be connected to the cathode electrode through the low potential line VSSL.

The driving transistor DT may include a first electrode connected to a second node N2, a second electrode connected to a third node N3, and a gate electrode connected to a first node N1. The driving transistor DT may provide a driving current Id to the light-emitting part 150 based on a voltage (or a data voltage stored in the capacitor Cst to be described below) of the first node N1.

The first transistor T1 may include a first electrode connected to the first node N1, a second electrode connected to the third node N3, and a gate electrode that receives a first scan signal SC1. The first transistor T1 may be turned on in response to the first scan signal SC1 and diode-connected between the first node N1 and the third node N3 to sample a threshold voltage (Vth) of the driving transistor DT. The first transistor T1 may be a compensation transistor.

The capacitor Cst may be connected or formed between the first node N1 and a fourth node N4. The capacitor Cst may store or maintain a provided high potential driving voltage EVDD.

The second transistor T2 may include a first electrode connected to a data line DL (or for receiving the data voltage Vdata), a second electrode connected to the second node N2, and a gate electrode that receives a second scan signal SC2. The second transistor T2 may be turned on in response to the second scan signal SC2 and may transmit the data voltage Vdata to the second node N2. The second transistor T2 may be a data supply transistor.

The third transistor T3 and the fourth transistor T4 (or first and second light-emitting control transistors) may be connected between the high potential driving voltage EVDD and the light-emitting part 150 and may form a current flowing path along which the driving current Id generated by the driving transistor DT flows.

The third transistor T3 may include a first electrode connected to the fourth node N4 and for receiving the high potential driving voltage EVDD, a second electrode connected to the second node N2, and a gate electrode that receives the light-emitting control signal EM.

The fourth transistor T4 may include a first electrode connected to the third node N3, a second electrode connected to the fifth node N5 (or the anode electrode of the light-emitting part 150), and a gate electrode that receives the light-emitting control signal EM.

The third and fourth transistors T3 and T4 are turned on in response to the light-emitting control signal EM, and in this case, the driving current Id may be provided to the light-emitting part 150, and the light-emitting part 150 may emit light with luminance corresponding to the driving current Id.

The fifth transistor T5 may include a first electrode that receives a bias voltage Vobs, a second electrode connected to the second node N2, and a gate electrode that receives a third scan signal SC3. The fifth transistor T5 may be a bias transistor.

The sixth transistor T6 may include a first electrode that receives a first initialization voltage Var, a second electrode connected to the fifth node N5, and a gate electrode that receives the third scan signal SC3.

The sixth transistor T6 may be turned on in response to the third scan signal SC3 before the light-emitting part 150 emits light (or after the light-emitting part 150 emits light) and may initialize the anode electrode (or the pixel electrode) of the light-emitting part 150 using the first initialization voltage Var.

The light-emitting part 150 may have a parasitic capacitor formed between the anode electrode and the cathode electrode. In addition, while the light-emitting part 150 emits light, the parasitic capacitor may be charged so that the anode electrode of the light-emitting part 150 may have a specific voltage. In particular, such a phenomenon may be noticeably when the display device is driven in the VRR mode.

Accordingly, the amount of charge accumulated in the light-emitting part 150 may be initialized by applying the first initialization voltage Var to the anode electrode of the light-emitting part 150 through the sixth transistor T6.

The first initialization voltage Var may be supplied through the anode reset line VAR_L connecting a supply source of the first initialization voltage Var, for example, the power supply unit 500, to the first electrode of the sixth transistor T6. The first initialization voltage Var may also be referred to as an “anode reset voltage.”

In the present specification, the gate electrodes of the fifth and sixth transistors T5 and T6 are formed to commonly receive the third scan signal SC3. However, the present disclosure is not necessarily limited thereto, and the gate electrodes of the fifth and sixth transistors T5 and T6 may be formed to be independently controlled by receiving separate scan signals.

The seventh transistor T7 may include a first electrode that receives a second initialization voltage Vini, a second electrode connected to the first node N1, and a gate electrode that receives a fourth scan signal SC4.

The seventh transistor T7 may be turned on in response to the fourth scan signal SC4 and may initialize the gate electrode of the driving transistor DT using the second initialization voltage Vini. Unnecessary charges may remain in the gate electrode of the driving transistor DT due to the high potential driving voltage EVDD stored in the capacitor Cst. Accordingly, the amount of the remaining charges may be initialized by applying the second initialization voltage Vini to the gate electrode of the driving transistor DT through the seventh transistor T7. The second initialization voltage Vini may also be referred to as an “gate reset voltage.”

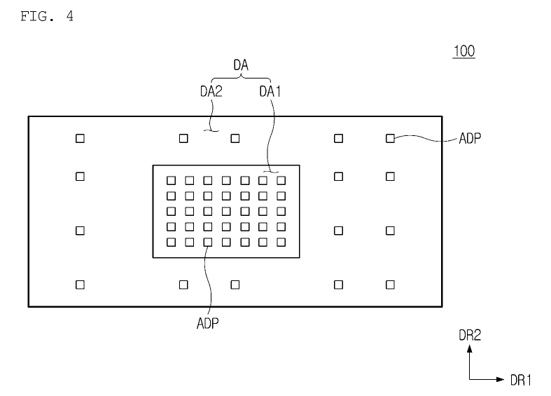

FIG. 4 is an example of a plan view of a display area of FIG. 1.

Referring to FIG. 4, the display area DA of the display panel 100 according to one implementation may include a first display area DA1 positioned in a central portion of the display area DA and a second display area DA2 surrounding the first display area DA1. Auxiliary pad electrodes ADP may be disposed in each of the display areas DA1 and DA2. According to one implementation, the number of auxiliary pad electrodes ADP per area in the central portion of the display area DA may be greater than the number of auxiliary pad electrodes ADP per area in the outer portion of the display area DA. For example, the number of auxiliary pad electrodes ADP per area in the first display area DA1 may be greater than the number of auxiliary pad electrodes ADP per area in the second display area DA2.

In addition, a pitch between adjacent auxiliary pad electrodes ADP in the first display area DA1 may be smaller than a pitch between adjacent auxiliary pad electrodes ADP in the second display area DA2.

FIG. 4 illustrates that the pitches of the auxiliary pad electrodes ADP or the number of auxiliary pad electrodes ADP per area in the second display area DA2 are constant, but the implementations of the present specification are not limited thereto, and the number of auxiliary pad electrodes ADP per area may decrease or the pitch between adjacent auxiliary pad electrodes ADP may decrease as the position moves away from the central portion of the display area DA.

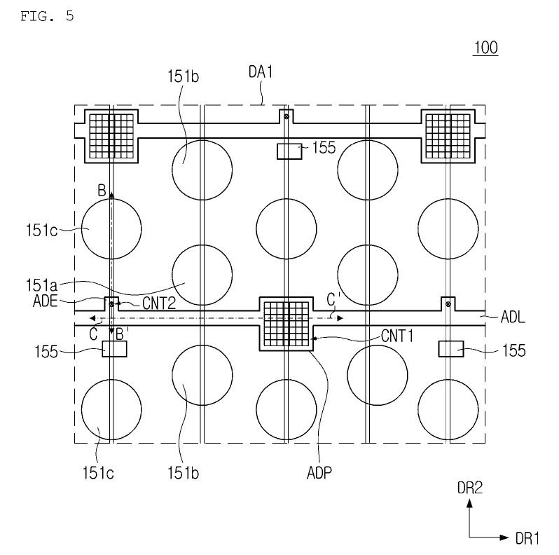

FIG. 5 is an example of a plan view of a first display area in FIG. 4.

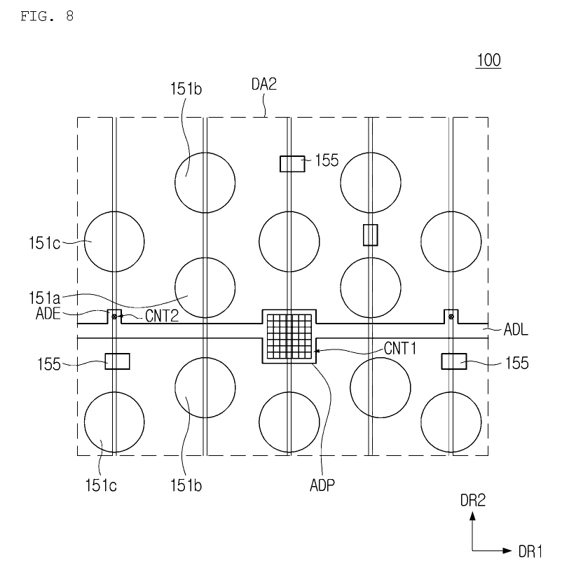

It is assumed that an area of a portion of the first display area DA1 illustrated in FIG. 5 is the same as an area of a portion of the second display area DA2 illustrated in FIG. 8, which will be described below.

Referring to FIG. 5, a plurality of anode electrodes 151a,151b, and 151c, the low potential line VSSL, the auxiliary pad electrode ADP, an auxiliary line ADL, and an auxiliary protruding electrode ADE may be disposed in the first display area DA1. Although not illustrated, cathode electrodes may be disposed across the entire first display area DA1.

A first anode electrode 151a and a second anode electrode 151b may be alternately disposed in the second direction DR2. For example, the first anode electrode 151a may be an anode electrode of a first sub-pixel (or a red pixel), and the second anode electrode 151b may be an anode electrode of a second sub-pixel (or a green pixel). The third anode electrode 151c may be disposed in the second direction DR2. The third anode electrode 151c may be positioned at the other side of the second anode electrode 151b in the first direction DR1 and the other side in the second direction DR2 and positioned at the other side of the first anode electrode 151a in the first direction DR1 and one side in the second direction DR2. The third anode electrode 151c may be an anode electrode of a third sub-pixel (or a blue pixel).

The auxiliary line ADL may be disposed between adjacent third anode electrodes 151c in the second direction DR2. The auxiliary line ADL may extend in the first direction DR1. The auxiliary line ADL may be disposed between the first anode electrode 151a and the second anode electrode 151b that are adjacent to each other in the second direction DR2. The auxiliary line ADL may be provided as a plurality of auxiliary lines, and the auxiliary pad electrode ADP may be disposed between adjacent auxiliary lines ADL. The auxiliary pad electrode ADP may be directly connected to adjacent auxiliary lines ADL. The auxiliary protruding electrodes ADE may protrude from the auxiliary line ADL in one direction. For example, the auxiliary protruding electrode ADE may protrude (or extend) from one side of the auxiliary line ADL in the second direction DR2, but the implementations of the present specification are not limited thereto. The auxiliary protruding electrode ADE may be directly connected to the auxiliary line ADL.

The low potential line VSS may extend in the second direction DR2.

The auxiliary pad electrode ADP may be electrically connected to the cathode electrode through a first contact hole CNT1. The auxiliary protruding electrode ADE may be electrically connected to the low potential line VSSL through a second contact hole CNT2.

The spacer 155 may be disposed in the first display area DA1. One spacer 155 may be disposed between adjacent third anode electrodes 151c, and the other spacer 155 may be disposed between the first anode electrode 151a and the second anode electrode 151b. One spacer 155 may be disposed between the auxiliary line ADL and the third anode electrode 153c.

The auxiliary line ADL may be disposed between adjacent third anode electrodes 151c in the second direction DR2 and between the first anode electrode 151a and the second anode electrode 151b that are adjacent to each other in the second direction DR2. Since the auxiliary line ADL is connected to the low potential line VSSL through the auxiliary protruding electrode ADE, a low potential DC voltage may be applied. Accordingly, it is possible to prevent parasitic capacitance from being generated between adjacent third anode electrodes 151c in the second direction DR2 or between the first anode electrode 151a and the second anode electrode 151b that are adjacent to each other in the second direction DR2.

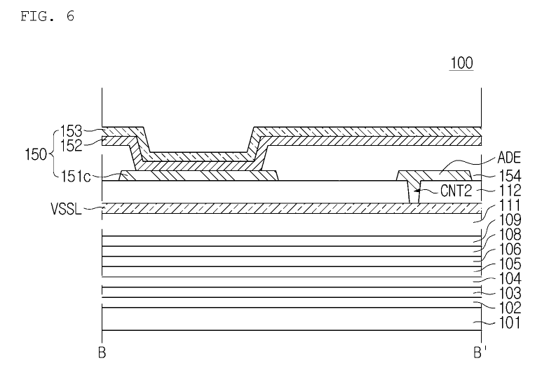

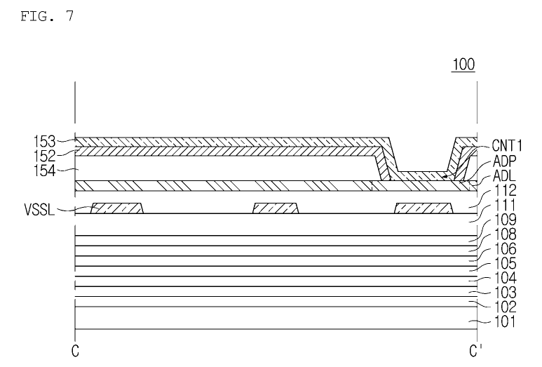

FIG. 6 is an example of a cross-sectional view along line B-B’ in FIG. 5. In the description of FIGS. 6 and 7, the detailed descriptions of the contents described in FIG. 3 will be omitted.

Referring to FIG. 6, the low potential line VSSL may be disposed on the first protective layer 111. The second protective layer 112 may be disposed on the low potential line VSSL. The third anode electrode 151c and the auxiliary protruding electrode ADE may be disposed on the second protective layer 112. For example, the third anode electrode 151c and the auxiliary protruding electrode ADE may be disposed on the same layer. The auxiliary protruding electrode ADE may be electrically connected to the low potential line VSSL through the second contact hole CNT2 passing through the second protective layer 112.

The third anode electrode 151c may be physically and electrically separated from the auxiliary protruding electrode ADE. The organic layer 152 may be disposed on the third anode electrode 151c, and the cathode electrode 153 may be disposed on the organic layer 152.

FIG. 7 is an example of a cross-sectional view along line C-C’ in FIG. 5.

Referring to FIG. 7, the low potential line VSSL may be disposed on the first protective layer 111, and the second protective layer 112 may be disposed on the low potential line VSSL. The auxiliary pad electrode ADP and the auxiliary line ADL may be disposed on the second protective layer 112. The auxiliary pad electrode ADP and the auxiliary line ADL may be disposed on the same layer and integrally connected. The bank 154 may be disposed on the auxiliary line ADL. The bank 154 may be removed from the second contact hole CNT2. An upper surface of the auxiliary pad electrode ADP may be exposed through the first contact hole CNT1.

The organic layer 152 may be disposed on the bank 154. The organic layer 152 may be removed from the first contact hole CNT1. However, the organic layer 152 may be disposed on an inner surface of the bank 154. In the implementations of the present specification, a disconnected area of the organic layer 152 may be the first contact hole CNT1, but is not limited thereto. The cathode electrode 153 may be disposed on the organic layer 152. The cathode electrode 153 may be in direct contact with the upper surface of the auxiliary pad electrode ADP exposed by the organic layer 152 and the bank 154 through the first contact hole CNT1. The cathode electrode 153 may be electrically connected to the auxiliary pad electrode ADP through the first contact hole CNT1.

FIG. 8 is an example of a plan view of a second display area in FIG. 4.

Referring to FIG. 8, the number of spacers 155 per area of the first display area DA1 described in FIG. 5 may be the same as the number of spacers 155 per area of the second display area DA2.

On the other hand, as described above in FIG. 4, the number of auxiliary pad electrodes ADP per area in the second display area DA2 may be less than the number of auxiliary pad electrodes ADP per area in the first display area DA1, and the pitch between adjacent auxiliary pad electrodes ADP in the second display area DA2 may be smaller than the pitch between adjacent auxiliary pad electrodes ADP in the first display area DA1.

According to the implementations of the present specification, since the low potential line VSSL is disposed to surround the display area DA as described in FIG. 1, a lower potential voltage in which a significant voltage drop has occurred may be applied to the pixels PX disposed closer to the central portion compared to the pixels PX disposed closer to the outer portion. Accordingly, a luminance imbalance across areas in the display area DA can occur.

In order to prevent this, it is possible to increase process time by increasing the number of first contact holes CNT1 through which the auxiliary pad electrodes ADP and the cathode electrode 153 may be electrically connected or decreasing the pitch between the first contact holes CNT1.

However, according to the implementations of the present specification, since the number of auxiliary pad electrodes ADP per area (or the number of first contact holes CNT1) in the first display area (see DA1 of FIG. 5) in which a significant voltage drop may occur is less than the number of auxiliary pad electrodes ADP per area (or the number of first contact holes CNT1) in the second display area DA2 in which a relatively small voltage drop occurs, a luminance imbalance across areas in the display area DA can be prevented without increasing the process time.

Hereinafter, other implementations will be described. The detailed description of the components already described in FIGS. 1 to 8 will be omitted.

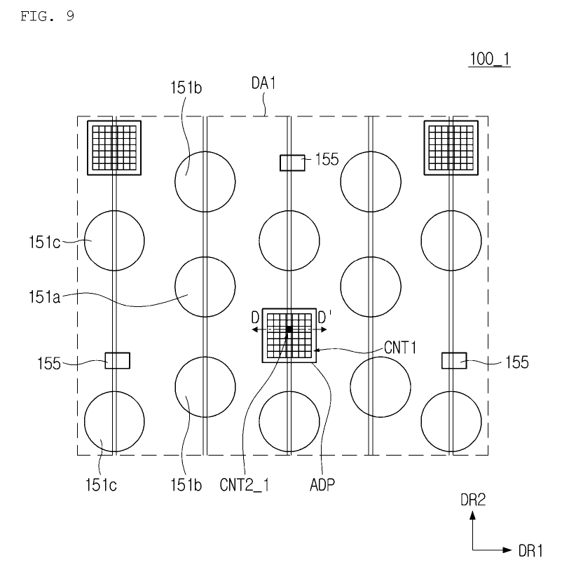

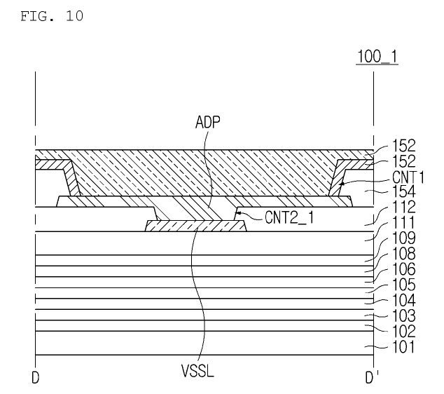

FIG. 9 is a plan view of an example of a first display area of a display panel according to another implementation. FIG. 10 is a cross-sectional view along line D-D’ in FIG. 9.

Referring to FIGS. 9 and 10, a display panel 100_1 according to the present implementation differs from the display panel 100 of FIG. 5 in that it does not include the auxiliary line ADL and auxiliary protruding electrode ADE of FIG. 5.

More specifically, the first contact hole CNT1 and a second contact hole CNT2_1 may overlap each other. The auxiliary protruding electrode ADP may be electrically connected to the low potential line VSSL through the second contact hole CNT2_1 passing through the second protective layer 112. Furthermore, the cathode electrode 153 may be electrically connected to the auxiliary pad electrode ADP through the first contact hole CNT1 passing through the bank 154 and the organic layer 152.

Even in the present implementation, the number of auxiliary pad electrodes ADP per area in the second display area DA2 (see FIG. 8) may be less than the number of auxiliary pad electrodes ADP per area in the first display area DA1, and the pitch between adjacent auxiliary pad electrodes ADP in the second display area DA2 may be smaller than the pitch between adjacent auxiliary pad electrodes ADP in the first display area DA1.

Accordingly, a luminance imbalance across the areas of the display area DA can be prevented without increasing the process time.

A display device according to various implementations of the present specification may be described as follows.

According to implementations of the present specification, there is provided a display device including a substrate including a display area including a plurality of pixels and a non-display area around the display area, a low potential line disposed on the substrate and extending along a first direction, a first electrode disposed on the low potential line and disposed in each sub-pixel of each pixel, a plurality of auxiliary pad electrodes, and a second electrode on an auxiliary pad electrode and on the first electrode, in which the display area includes a first display area and a second display area between the first display area and the non-display area, the second electrode is electrically connected to the auxiliary pad electrode through a first contact hole, and the number of auxiliary pad electrodes per area in a central portion of the display area is greater than the number of auxiliary pad electrodes per area in an outer portion of the display area.

In the display device according to the implementations of the present specification, the display area may include the first display area and the second display area between the first display area and the non-display area, and the number of the auxiliary pad electrodes per area in the first display area may be greater than the number of the auxiliary pad electrodes per area in the second display area.

In the display device according to the implementations of the present specification, a pitch between adjacent auxiliary pad electrodes in the first display area may be smaller than a pitch between adjacent auxiliary pad electrodes in the second display area.

In the display device according to the implementations of the present specification, the first electrode and the auxiliary pad electrode may be disposed on the same layer.

In the display device according to the implementations of the present specification, the auxiliary pad electrode may be electrically connected to the low potential line through a second contact hole.

In the display device according to the implementations of the present specification, the display device may further include an auxiliary line extending along a second direction intersecting the first direction, and the auxiliary line may be electrically connected to the auxiliary pad electrode.

In the display device according to the implementations of the present specification, the pixel may include a first sub-pixel, a second sub-pixel, and a third sub-pixel, the auxiliary line may be disposed on the same layer as the first electrode, and the auxiliary line may be disposed between adjacent third sub-pixels in the second direction, and between the first sub-pixel and the second sub-pixel that are adjacent each other in the second direction.

In the display device according to the implementations of the present specification, the display device may further include an auxiliary protruding electrode connected to the auxiliary line and protruding from the auxiliary line in the first direction, in which the auxiliary protruding electrode may be electrically connected to the low potential line through a second contact hole.

In the display device according to the implementations, it is possible to minimize the voltage drop of the low potential voltage in the central portion of the display area by designing the number of contact area per area or pitches between the low potential line, the auxiliary electrode, and the second electrode differently in the central portion and outer portion of the display area.

However, effects obtainable from the present specification are not limited to the above effects, and other effects that are not described will be able to be clearly understood by those skilled in the art to which the present specification pertains based on the following description.

Although the implementations of the present disclosure have been described above with reference to the accompanying drawings, those skilled in the art to which the present disclosure pertains will be able to understand that the above-described technical configuration of the present disclosure can be carried out in other specific forms without changing the technical spirit or essential features thereof. Accordingly, it should be understood that the above-described implementations are illustrative and not restrictive in all respects. In addition, the scope of the present disclosure is described by the claims to be described below rather than the detailed description. In addition, the meaning and scope of the claims and all changed or modified forms derived from the equivalent concept should be construed as being included in the scope of the present disclosure.

What is claimed is:

1. A display device comprising:
a substrate including (i) a display area including a plurality of pixels that each include a plurality of sub-pixels, and (ii) a non-display area around the display area;
a low potential line disposed on the substrate and extending along a first direction;
a first electrode disposed on the low potential line and disposed in each of the plurality of sub-pixels;
a plurality of auxiliary pad electrodes; and
a second electrode disposed on an auxiliary pad electrode among the plurality of auxiliary pad electrodes and on the first electrode,
wherein the display area includes a first display area and a second display area between the first display area and the non-display area,
wherein the second electrode is electrically connected to the auxiliary pad electrode through a first contact hole, and
a number of auxiliary pad electrodes, among the plurality of auxiliary pad electrodes, per area in a central portion of the display area is greater than a number of auxiliary pad electrodes, among the plurality of auxiliary pad electrodes, per area in an outer portion of the display area.

2. The display device of claim 1, wherein the display area includes the first display area and the second display area between the first display area and the non-display area, and
wherein a number of auxiliary pad electrodes, among the plurality of auxiliary pad electrodes, per area in the first display area is greater than a number of auxiliary pad electrodes, among the plurality of auxiliary pad electrodes, per area in the second display area.

3. The display device of claim 2, wherein a pitch between adjacent auxiliary pad electrodes in the first display area is smaller than a pitch between adjacent auxiliary pad electrodes in the second display area.

4. The display device of claim 2, wherein the first electrode and the auxiliary pad electrode are disposed on the same layer.

5. The display device of claim 1, wherein the auxiliary pad electrode is electrically connected to the low potential line through a second contact hole.

6. The display device of claim 2, further comprising an auxiliary line extending along a second direction intersecting the first direction, and the auxiliary line is electrically connected to the auxiliary pad electrode.

7. The display device of claim 6, wherein the plurality of sub-pixels include a first sub-pixel, a second sub-pixel, and a third sub-pixel,
wherein the auxiliary line is disposed on the same layer as the first electrode, and the auxiliary line is disposed between adjacent third sub-pixels that are adjacent along the second direction and between the first sub-pixel and the second sub-pixel that are adjacent along the second direction.

8. The display device of claim 6, further comprising an auxiliary protruding electrode connected to the auxiliary line and protruding from the auxiliary line in the first direction,
wherein the auxiliary protruding electrode is electrically connected to the low potential line through a second contact hole.

9. The display device of claim 1, further comprising a spacer disposed between the first electrode and the second electrode,
wherein the number of the spacers per area in the central portion of the display area is the same as the number of the spacers per area in the outer portion of the display area.
